(19) United States
(12) Patent Application Publication
(10) Pub. No.: US 2013/0171797 A1
(43) Pub. Date: Jul. 4, 2013

(54) METHOD FOR FORMING MULTI-COMPONENT LAYER, METHOD FOR FORMING MULTI-COMPONENT DIELECTRIC LAYER AND METHOD FOR FABRICATING SEMICONDUCTOR DEVICE

(71) Applicants: Kyung-Woong PARK, Gyeonggi-do (KR); Kee-Jeung LEE, Gyeonggi-do (KR); Jae-Hyoung KOO, Gyeonggi-do (KR); Kwan-Woo DO, Gyeonggi-do (KR); Ji-Hoon AHN, Gyeonggi-do (KR); Woo-Young PARK, Gyeonggi-do (KR)

(72) Inventors: Kyung-Woong PARK, Gyeonggi-do (KR); Kee-Jeung LEE, Gyeonggi-do (KR); Jae-Hyoung KOO, Gyeonggi-do (KR); Kwan-Woo DO, Gyeonggi-do (KR); Ji-Hoon AHN, Gyeonggi-do (KR); Woo-Young PARK, Gyeonggi-do (KR)

(21) Appl. No.: 13/463,215

(22) Filed: May 3, 2012

(30) Foreign Application Priority Data
Jan. 2, 2012 (KR) 10-2012-0000161

(51) Int. Cl. H01L 21/31; H01L 21/336; H01L 21/02

(52) U.S. Cl. 438/381; 438/766; 438/585; 257/E21.24; 257/E21.008; 257/E21.409

(57) ABSTRACT

A method of forming a multi-component dielectric layer on the surface of a substrate by atomic layer deposition includes injecting a cocktail source of a plurality of sources at least having a cyclopentadienyl ligand, wherein the cocktail source is adsorbed on a surface of a substrate by injecting the cocktail source, performing a first purge process to remove a non-adsorbed portion of the cocktail source, injecting a reactant to react with the adsorbed cocktail source, wherein a multi-component layer is formed by the reaction between the reactant and the absorbed cocktail source, and performing a second purge process to remove reaction byproducts and an unreacted portion of the reactant.

### CROSS-REFERENCE TO RELATED APPLICATIONS

The present application claims priority of Korean Patent Application No. 10-2012-0000161, filed on Jan. 2, 2012, which is incorporated herein by reference in its entirety.

### BACKGROUND

1. Field

Exemplary embodiments of the present invention relate to a method for forming a semiconductor device, and more particularly, to a method for forming a multi-component layer, a method for forming a multi-component dielectric layer and a method for fabricating a semiconductor device.

2. Description of the Related Art

As the level of integration of semiconductor memory devices, such as DRAMs, is increasing, the cross-sectional area of cells in the devices is decreasing. Thus, securing sufficient capacitance of a capacitor for a semiconductor operation may be difficult in a highly integrated semiconductor memory device. Particularly, forming a capacitor on a substrate having the capacitance required for operation in a gigabit DRAM is difficult. Thus, various methods for securing the capacitance of capacitors have been proposed.

Developing multi-component dielectric layers comprising HfO₂, Ta₂O₅, Nb₂O₅, etc., which have a dielectric constant (k) higher than Al₂O₃ and ZrO₂, may be useful in the development of ultra-large-scale integration DRAMs of 30 nm or smaller. However, multi-component dielectric layers show deterioration in interfacial properties due to a crystallization heat-treatment at a high temperature, undergo deterioration in dielectric properties due to a local non-uniformity of the layer composition, and cause leakage current. Due to these features, these multi-component dielectric layers are difficult to apply to semiconductor memory devices.

In attempts to overcome these shortcomings, there have been studies on improving dielectric properties, such as permittivity, either by using a layer for promoting low-temperature crystallization or by doping the multi-component dielectric layers with heterogeneous elements to induce phase transition. However, when multi-component dielectric layers are formed according to a nano-laminate method, the burden for managing a process for forming each layer increases, the layer composition is difficult to control, and the process time increases to reduce productivity.

### SUMMARY

An embodiment of the present invention is directed to a method for forming a multi-component layer, a method for forming a multi-component dielectric layer and a method for fabricating a semiconductor device that may control the composition of the multi-component dielectric layer, increase the uniformity of the multi-component dielectric layer composition, promote the bonding between the components of the multi-component dielectric layer to achieve excellent layer properties, and prevent leakage current.

In accordance with an embodiment of the present invention, a method of forming a multi-component layer on the surface of a substrate includes: injecting a cocktail source of a plurality of sources at least having a cyclopentadienyl ligand, wherein the cocktail source is adsorbed on a surface of a substrate by injecting the cocktail source; performing a first purge process to remove a non-adsorbed portion of the cocktail source; injecting a reactant to react with the adsorbed cocktail source, wherein a multi-component layer is formed by the reaction between the reactant and the absorbed cocktail source; and performing a second purge process to remove reaction byproducts and an unreacted portion of the reactant.

In accordance with an another embodiment of the present invention, a method of forming a multi-component dielectric layer on the surface of a substrate by atomic layer deposition includes: injecting a cocktail source of a tantalum source having a cyclopentadienyl ligand and a zirconium source having a cyclopentadienyl ligand, wherein the cocktail source is adsorbed on a substrate by injecting the cocktail source; performing a first purge process to remove a non-adsorbed portion of the cocktail source; injecting an oxidant to react with the adsorbed cocktail source, wherein an oxide containing zirconium and tantalum is formed by the reaction between the oxidant and the absorbed cocktail source; and performing a second purge process to remove reaction byproducts and an unreacted portion of the oxidant.

In accordance with yet another embodiment of the present Invention, a method for fabricating a capacitor includes: forming a storage node; reacting an oxidant with a cocktail source including a tantalum source having a cyclopentadienyl ligand and a zirconium source having a cyclopentadienyl ligand, wherein a first oxide layer containing zirconium and tantalum is formed over the storage node by the reaction between the oxidant and the cocktail source; and forming a plate over the first oxide layer.

In accordance with still another embodiment of the present invention, a method for fabricating a transistor includes: adsorbing a cocktail source of a tantalum source having a cyclopentadienyl ligand and a zirconium source having a cyclopentadienyl ligand on a semiconductor substrate; reacting the cocktail source with an oxidant to form a gate insulating layer comprising an oxide layer containing zirconium and tantalum; and forming a gate electrode over the gate insulating layer.

### BRIEF DESCRIPTION OF THE DRAWINGS

FIG. 1 illustrates a process sequence for forming a multi-component dielectric layer in accordance with an embodiment of the present invention.

FIG. 2 illustrates a pulse sequence for depositing TaZrO.

FIGS. 3A to 3E illustrates a method for fabricating a capacitor in accordance with an embodiment of the present invention.

FIG. 4 illustrates a modification of a capacitor comprising a multi-component dielectric layer in accordance with an embodiment of the present invention.

FIGS. 5A to 5D illustrate a comparison of properties obtained by applying a zirconium source having a cyclopentadienyl ligand in accordance with an embodiment of the present invention.

FIGS. 6A to 6C illustrate a method for fabricating a transistor comprising a multi-component dielectric layer in accordance with an embodiment of the present invention.

FIG. 7 illustrates a modification of a transistor comprising a multi-component dielectric layer in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Generally, sources (precursors) such as ZrO₂, Ta₂O₅ and Nb₂O₅, which are used in dielectric layers, have ligands, such as TEMA- (tetra ethyl methyl amino-, [-(NMeEt)₄)]), TBTDE- (t-butyl-tri diethyl amino-, [t-Bu-(NEt₂)₃]), TBTDM- (t-butyl-tri dimethyl amino-, [t-Bu-(NMe₂)₃]), and TBTEM- (t-butyl-tri ethyl methyl amino-, [t-Bu-(NMeEt)₃]). However, TEMAZr, which has an amino bond, is thermally decomposed at a temperature of 275° C. or higher, while top overhang and poor step coverage occur as a result of a chemical vapor deposition (CVD) reaction. In addition, in dielectric layers such as Ta₂O₅ layers, which require crystallization heat-treatment at 750° C. or higher, a dense thin layer resulting from an increase in the process temperature is formed, and reducing the crystallization temperature below 600° C. is a key factor to reducing a thermal budget. Also, when Ta₂O₅ is deposited using a source such as TBTDETa, the source is thermally decomposed at 320° C. or higher, but there is a limitation in forming a dense layer at the atomic layer deposition (ALD) process temperature.

Thus, in an embodiment of the present invention, a source having a cyclopentadienyl ligand is used in place of a source having an amino bond, and the thermal decomposition of the source having a cyclopentadienyl ligand is initiated at low temperatures. The cyclopentadienyl ligand increases the thermal stability of the source itself and maintains the reactivity of the source with a reactant, thus an atomic layer deposition of the source may be performed at high temperatures.

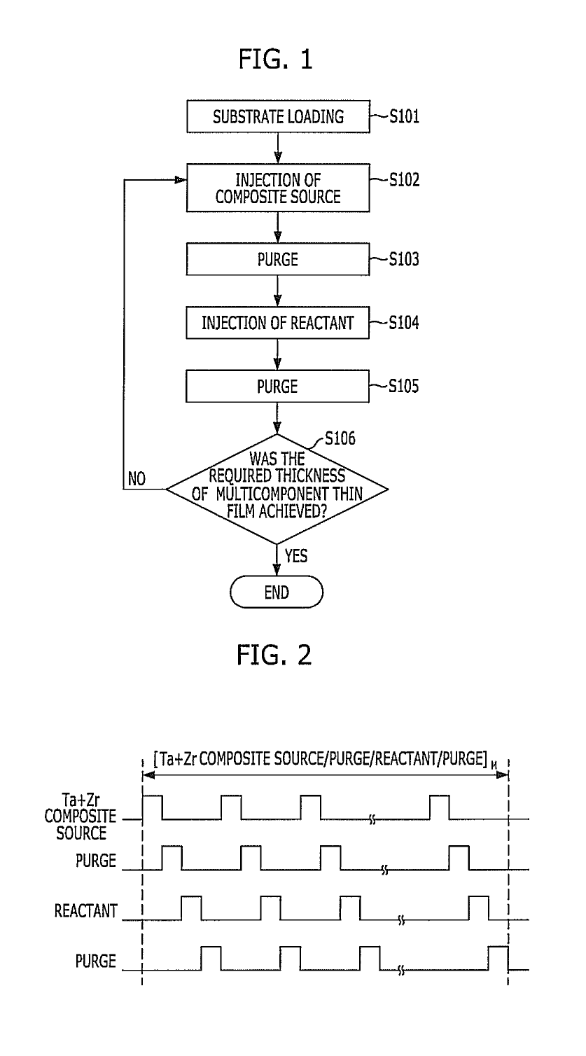

FIG. 1 illustrates a process sequence for forming a multi-component dielectric layer according to an embodiment of the present invention.

Referring to FIG. 1, a multi-component dielectric layer according to an embodiment of the present invention is formed by an atomic layer deposition (ALD) process using a cocktail source. The multi-component dielectric layer may comprise an oxide containing element A and element B, or more specifically, an ‘ABO’ thin layer. Element A and element B may include a transition metal element such as Zr or Ta. Thus, the ABO thin layer may be formed of a metal oxide, for example, ZrTaO.

The atomic layer deposition (ALD) process using the cocktail source is performed using a mixture of source A and source B. Source A and source B are also referred to as precursor A and precursor B, respectively, and the cocktail source is also referred to as a cocktail precursor. A cyclopentadienyl (Cp) ligand may be bonded to the cocktail source. The cyclopentadienyl ligand increases the thermal stability of the source itself and maintains the reactivity of the source with a reactant, thus an atomic layer deposition of the source may be performed at high temperatures. When the cocktail source prepared by mixing sources as described above is used, process stability may be improved and the composition of a multi-component dielectric layer to be controlled. When the cocktail source Is a cocktail source of source A and source B, any one or both of source A and source B has a cyclopentadienyl ligand.

Source A and source B may comprise a metal element. For example, source A and source B comprise any one of Zr, Ta, and Nb. A Zr source may comprise Cp-TDMAZr [Cp-Zr(NMe₂)₃] or Cp-TDEAZr [(Cp-zr(NEt₂)₃]. A Ta source may comprise Cp-TDETa [Cp-Ta(NEt₂)₄], Cp-TDMTa [Cp-Ta(NMe₂)₄], or Cp-TBTDETa [Cp-Ta-tBu(NEt₂)₃]. A Nb source may comprise Cp₂Nb(H)(CO) or CpNb(CO)₄.

Hereafter, a method of forming a multi-component dielectric layer by an atomic layer deposition (ALD) process using a cocktail source will be described in comparison with a method of forming a multi-component dielectric layer by a conventional ALD process. The description will be made by taking a multi-component oxide, more specifically, an ‘ABO’ thin layer comprising element A and element B, as an example of the multi-component dielectric layer.

The atomic layer deposition (ALD) process comprises a unit cycle consisting of sequential steps of source injection, purge, reactant injection, and purge. During the atomic layer deposition (ALD) process, the unit cycle is repeated several times, thereby depositing a layer having a designated thickness.

First, a method of forming an ABO thin layer by a conventional atomic layer deposition process will be described.

(Unit Cycle 1)

[{(source A/purge/reactant/purge)ₙ}+{(source B/purge/reactant/purge)ₘ}]_{N}

In unit cycle 1, ‘source A’ and ‘source B’ are steps of injecting the sources into a chamber, thereby adsorbing the sources on a designated layer. Also, ‘reactant’ is a step of injecting a material that reacts with the adsorbed sources to form an oxide, and ‘purge’ is a step of removing a non-reacted portion of the sources and reaction byproducts from the chamber. A factor determining the composition of the ABO thin layer is the number of cycles (m and n), and the ABO thin layer is in the form of a laminate of an A oxide (AO) and a B oxide (BO). When this method is used, the A oxide (AO) and the B oxide (BO) are independently present, such that the inherent properties of the oxide layers are maintained. For this reason, to change these oxides into the form of a multi-component oxide, such as an ABO thin layer, or to form a crystalline phase having high permittivity from these oxides, subsequent heat treatment of these oxides at very high temperatures is further performed. However, a diffusion/reaction layer may be formed between the multi-component dielectric layer and the material contacting therewith, or the composition of the multi-component dielectric layer becomes non-uniform due to the difference in diffusion rate between the components of the composition of the multi-component dielectric layer when subsequent heat-treatments are performed.

In an embodiment of the present invention, a multi-component dielectric layer is formed by an atomic layer deposition process using a cocktail source without using the conventional atomic layer deposition process.

The method of forming the multi-component dielectric layer by the atomic layer deposition process using the cocktail source will now be described in detail with reference to FIG. 1. For reference, the atomic layer decomposition process according to an embodiment of the present invention uses the cocktail source to increase the uniformity of the composition of small amounts of metal elements injected into a thin layer and to promote the reaction between components. In addition, an ABO thin layer comprising a cocktail source of the A oxide (AO) and the B oxide (BO) has increased permittivity and, at the same time, has reduced leakage current. For example, any one of the A oxide and the B oxide has high permittivity, and thus increases the permittivity of the layer, and the other oxide has high band gap energy, and thus reduces the leakage current of the layer.

Referring to FIG. 1, a substrate is loaded into an ALD chamber (S101). A multi-component dielectric layer is to be deposited on the substrate. Subsequently, a cocktail source is injected into the chamber such that the cocktail source is adsorbed on the substrate (S102). Next, a purge process is performed to remove a non-adsorbed portion of the cocktail source (S103). Subsequently, a reactant is injected into the chamber to induce a reaction with the adsorbed cocktail source (S104). As a result, a multi-component monolayer layer is deposited. Finally, a purge process is performed to remove reaction products (S105). The sequential steps of cocktail source injection, purge, reactant injection, and purge are repeated until the designated thickness of the multi-component dielectric layer is obtained (S106).

A unit cycle consisting of sequential steps of cocktail source injection, purge, reactant injection, and purge is as follows.

(Unit Cycle 2)

[{(cocktail source/purge/reactant/purge)]_{N}

In unit cycle 2, ‘cocktail source’ is a step of injecting a cocktail source of source A and source B to adsorb these sources on a designated layer. Also, ‘reactant’ is a step of injecting a material that reacts with the adsorbed cocktail source to form an ABO thin layer, and ‘purge’ is a step of removing a non-reacted portion of the cocktail source and reaction byproducts from the chamber. In order to achieve the optimal composition ratio of element A and element B in the ABO thin layer, the mole concentrations of element A and element B may be controlled to a designated optimal mixing ratio.

For example, when the ABO thin layer comprises a multi-component oxide such as ‘TaZrO’, a method for depositing TaZrO is as follows.

FIG. 2 illustrates a pulse sequence for depositing TaZrO.

(Unit Cycle 3)

[{(Ta+Zr cocktail source/purge/O₃/purge)]_{N}

In unit cycle 3, ‘Ta+Zr cocktail source’ is a step of injecting a cocktail source of a Ta source and a Zr source to adsorb a Ta+Zr cocktail source on a designated layer. ‘O₃’ is a step of injecting an oxidant that reacts with the adsorbed Ta+Zr cocktail source to form a TaZrO thin layer. When the oxidant is injected, Ta and Zr, which are the central metals of the adsorbed Ta+Zr cocktail source, chemically react with the O₃ oxygen atoms to form a ZrTaO thin layer. The central metals have a very high reactivity with oxygen atoms and react with oxygen atoms to cause ligand exchange, and the ligands bonded to the central metals are separated rapidly from the central metals. Examples of the oxidant include an activated oxidant capable of generating oxygen radicals. Examples of the activated oxidant include ozone and plasma O₂, which are produced by a plasma generator. In unit cycle 3, ‘purge’ is a step of removing an unreacted portion of the Ta+Zr cocktail source and reaction byproducts from the chamber.

The Ta source and the Zr source comprise a cyclopentadienyl (Cp) ligand and may further comprise an ethyl (C₂H₅, Et) ligand or a methyl (CH₃, Me) ligand. For example, the Ta source may comprise Cp-TDETa[Cp-Ta(NEt₂)₄], Cp-TDMTa[Cp-Ta(NMe₂)₄], or Cp-TBTDETa[Cp-Ta-tBu(NEt₂)₃]. The Zr source may comprise Cp-TDMAZr[Cp-Zr(NMe₂)₃] or Cp-TDEAZr[(Cp-Zr(NEt₂)₃]. The Ta+Zr cocktail source is a mixed source of the Ta source and the Zr source. The Ta source and the Zr source have the same ligand, more specifically, the cyclopentadienyl (Cp) ligand. Because the Ta source and the Zr source have the same ligand (cyclopentadienyl ligand), the two sources are easily mixed.

Formulas 1 to 4 show examples of a cocktail source of a Ta source and a Zr source.

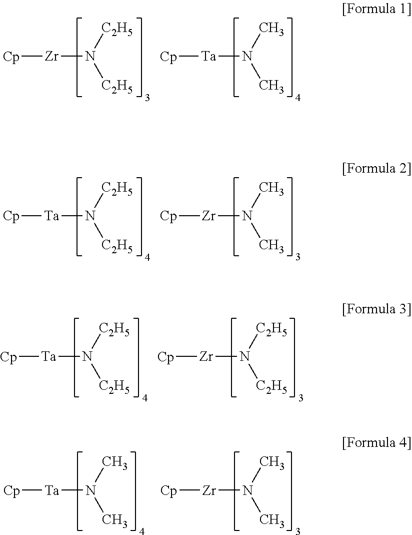

Referring to formulas 1 to 4, the Zr source may comprise CpZr(N(C₂H₅)₂)₃ or CpZr(N(CH₃)₂)₃, and the Ta source may comprise CpTa(N(C₂H₅)₂)₄ or CpTa(N(CH₃)₂)₄. Thus, the Zr source and the Ta source commonly have the cyclopentadienyl (Cp) ligand.

Because the Ta source and the Zr source commonly have the cyclopentadienyl (Cp) ligand, these sources may be mixed with each other. For example, CpZr(N(C₂H₅)₂)₃ and CpTa(N(CH₃)₂)₄ may be mixed. Also, CpZr(N(CH₃)₂)₃ and CpTa(N(C₂H₅)₂)₄ may be mixed. Also, CpZr(N(C₂H₅)₂)₃ and CpTa(N(C₂H₅)₂)₄ may be mixed. Also, CpZr(N(CH₃)₂)₃ and CpTa(N(CH₃)₂)₄ may be mixed.

The oxidant that is used in the present invention may be an oxygen-containing material comprising at least one selected from the group consisting of O₃, O₂ plasma, N₂O, and H₂O. A purge gas that is used in the purge step may comprise argon (Ar).

In order to control the composition ratio of Ta in the TaZrO thin layer (Ta/Ta+Zr) and the composition ratio of Zr in the thin layer (Zr/Zr+Ta), the mixing ratio of the Ta source and the Zr source may be controlled. For example, the mixing ratio of the Ta source and the Zr source may be controlled within the range of 3-60% such that the composition ratio of Ta is 3-30%.

In addition, when the cocktail source is an oxide of three components (ABCO), a cocktail source of an A source, a B source, and a C source may be injected. In this example, the A source, the B source, and the C source all have the same ligand (cyclopentadienyl ligand).

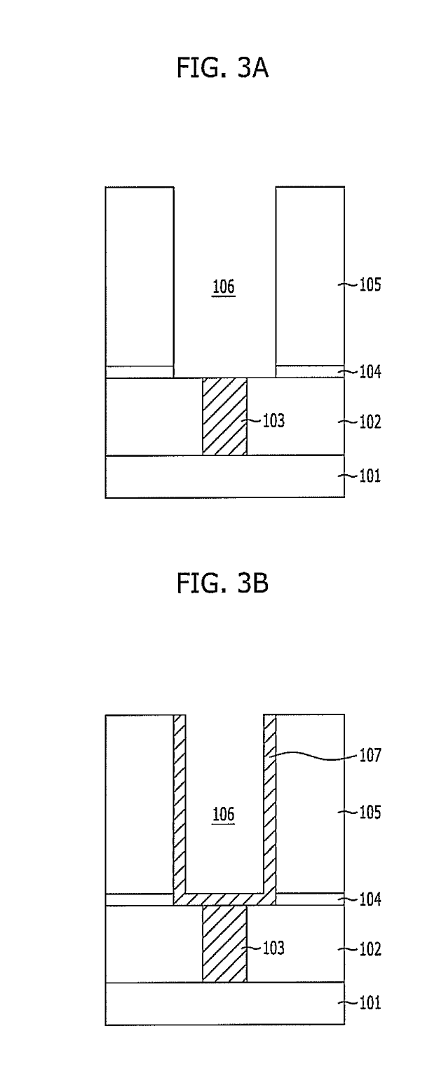

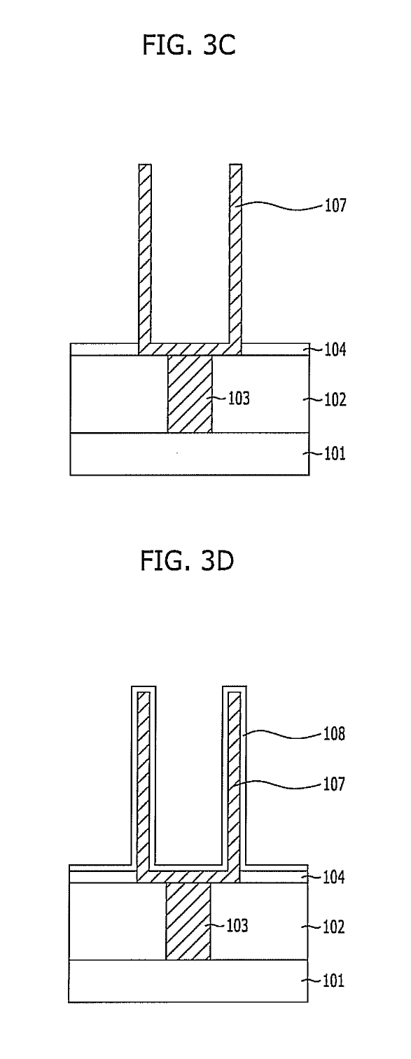

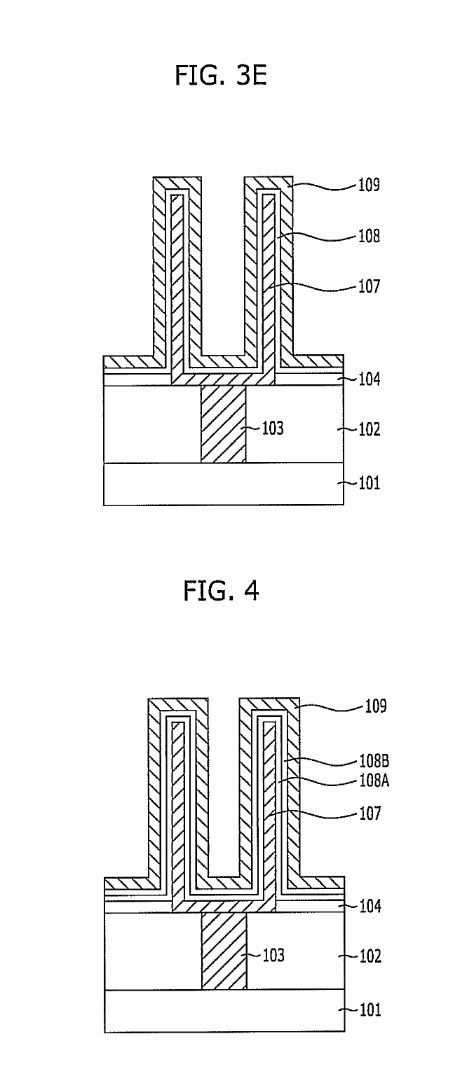

FIGS. 3A to 3E illustrate a method for fabricating a capacitor comprising a multi-component dielectric layer in accordance with an embodiment of the present invention.

Although a semiconductor device comprising a cylinder-type storage node is provided by example, the storage node may be of a concave type, a pillar type or the like, depending on the structure of the semiconductor device.

As shown in FIG. 3A, an interlayer insulating layer 102 is formed on a semiconductor substrate 101, and a storage node contact plug 103 is subsequently formed through the interlayer insulating layer 102. The substrate may include a formed structure.

Subsequently, an etch stop layer 104 and a mold layer 105 are sequentially formed on the interlayer insulating layer 102 having the storage node contact plug 103 formed therein. Subsequently, the mold layer 105 and the etch stop layer 104 are selectively etched, thereby forming an open portion 106 exposing the storage node contact plug 103.

As shown in FIG. 3B, a conductive layer is formed along the surface of the structure including the open portion 106. The conductive layer may include a transition metal nitride. For example, the conductive layer may be formed of a material such as TIN, TaN, TiAlN, TiSiN, TaCN, TiCN, TaAlN or TaAlN.

Subsequently, the conductive layer is subjected to a storage node isolation process, thereby forming a storage node 107.

As shown in FIG. 3C, the mold layer 105 is removed by a wet dip-out process. After the wet dip-out process, the storage node 107 may have a cylinder shape.

Although not shown, an anti-reaction layer may be formed on the surface of the storage node 107 after the wet dip-out process. The anti-reaction layer serves to suppress an interfacial reaction between the storage node 107 and a multi-component dielectric layer to be formed in a subsequent process. The anti-reaction layer may be formed of an oxide layer. The anti-reaction layer may suppress the interfacial reaction and, at the same time, act as a buffer layer between the multi-component dielectric layer and the storage node 107.

The anti-reaction layer may be formed by oxidizing the exposed surface of the storage node 107 by O₂ plasma treatment or O₃ plasma treatment. If the storage node 107 has a three-dimensional structure, the anti-reaction layer is preferably formed by ozone plasma treatment. Also, the anti-reaction layer may be formed by depositing an oxide layer using an atomic layer deposition (ALD) that has excellent step coverage. For example, when the storage node 107 is formed of titanium nitride (TiN), the anti-reaction layer may be formed by depositing titanium oxide (TiO₂) along the surface of the storage node 107 using the atomic layer deposition process.

The anti-reaction layer may comprise an oxide layer having a thickness of less than 30 Å. If the anti-reaction layer comprises an oxide, the anti-reaction layer is subjected to a process such as an O₂ plasma treatment or O₃ treatment process. This treatment process is preferably performed by plasma oxidation in an oxygen radical-dominant atmosphere at high pressure (>1 torr) such that the SN microbridge defects of the storage node are eliminated and an oxide layer is easily formed on the bottom of the three-dimensional structure. Meanwhile, an oxide of the same transition metal as that contained in the storage node 107 may also be deposited. For example, if the storage node is formed of TiN, a very thin titanium oxide (TiO₂) layer formed using the ALD process may likewise serve as an anti-reaction layer.

As shown in FIG. 3D, a multi-component dielectric layer 108 is formed along the surface of the structure including the storage node. In this embodiment, the multi-component dielectric layer 108 is formed by an atomic layer deposition process using a cocktail source. The multi-component dielectric layer 108 may comprise a multi-component oxide. For example, the multi-component dielectric layer 108 may comprise TaZrO, as shown in FIG. 2 and unit cycle 3.

After the multi-component dielectric layer 108 is deposited, it is subjected to post-treatment to control the stoichiometric composition of the multi-component dielectric layer having many defect sites such as oxygen vacancies. This post-treatment supplies oxygen to the multi-component dielectric layer 108. This post-treatment may be performed under the same conditions as the process of forming the anti-reflection layer on the storage node 107.

Also, to improve the dielectric properties of the multi-component dielectric layer 108, a heat-treatment process may be performed. The heat-treatment process may be carried out to secure a driving force required for the phase transition of the multi-component dielectric layer 108 to a material having high permittivity, or to supply oxygen to the layer, or to promote the reaction between heterogeneous metal components in the layer.

As shown in FIG. 3E, a plate 109 is formed on the multi-component dielectric layer 108. For example, the plate 109 may comprise a transition metal nitride such as TiN, TaN, TiAlN, TiCN or TaCN. The transition metal nitride may be formed in an atmosphere such as NH₃, N₂ plasma, or H₂ plasma. Also, to suppress a direct reduction reaction on the surface of the multi-component dielectric layer 108 or the formation of an oxygen-deficient layer on the layer 108, the formation of the plate 109 may be performed at low temperature (350° C. or below) in a non-reducing atmosphere such as N₂ plasma.

In another embodiment, an additional plate may be formed on the plate 109. The additional plate may comprise a material that may be formed at low temperature, such as boron-doped poly SiGe or boron/carbon-doped poly Si. An amorphous or crystalline silicon layer may serve not only as a hydrogen barrier, but also as a hard mask in a plate patterning process. A capping layer may further be formed on the additional layer. The capping layer may comprise a silicon-containing material, a binary oxide, a transition metal oxide, and a transition metal nitride. For example, the capping layer comprises a material having an amorphous phase at a low temperature, such as B-doped Si, SiGe, W, Ru, WN, TaN, TiN, SiO₂, Al₂O₃, TiO₂, ZrO₂, HfO₂, Ta₂O₅, or Nb₂O₅.

FIG. 4 illustrates a modification of the capacitor comprising the multi-component dielectric layer in accordance with an embodiment of the present invention.

Referring to FIG. 4, a multi-component dielectric layer 108A is formed between the storage node 107 and the plate 109. A dielectric layer 108B for controlling leakage current characteristics may further be formed on the multi-component dielectric layer 108A. The dielectric layer 108B may comprise the component of the multi-component dielectric layer 108A and an oxide of at least one transition metal. In addition, the dielectric layer 108B may comprise a material having higher band gap energy to control leakage current characteristics. For example, the dielectric layer 108B may be formed of a material such as ZrO₂, HfO₂, Al₂O₃, Al—ZrO₂, ZrHfO₂, La_{2O3}, LaHfOₓ, LaZrOₓ, ZrTaOₓ, ZrHfSiOₓ, ZrSiOₓ, HfSiOₓ, or Al—HfOₓ.

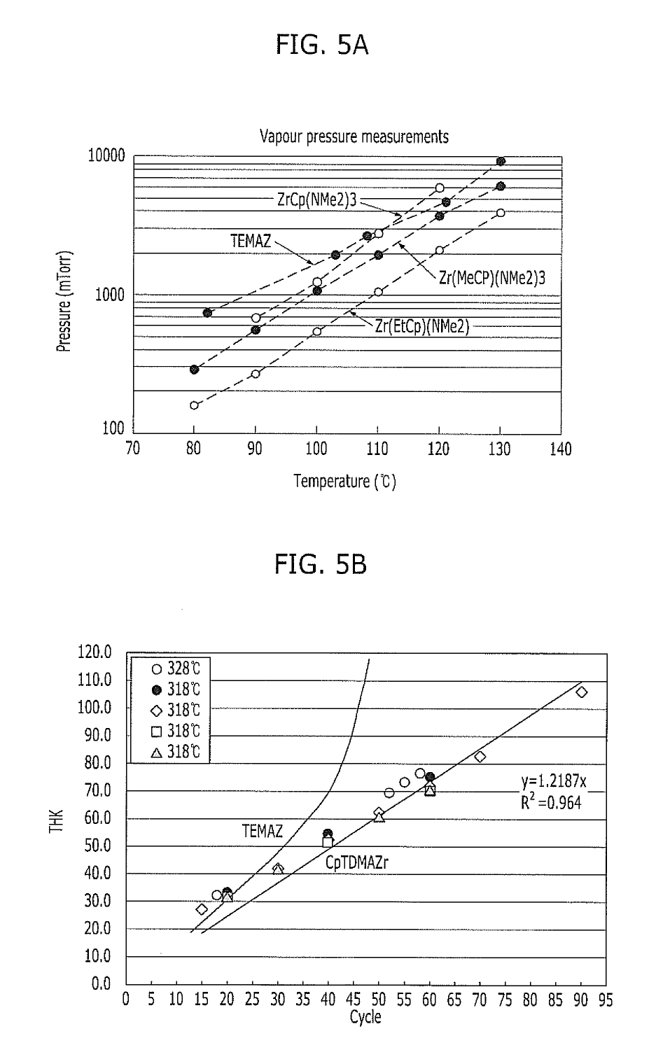

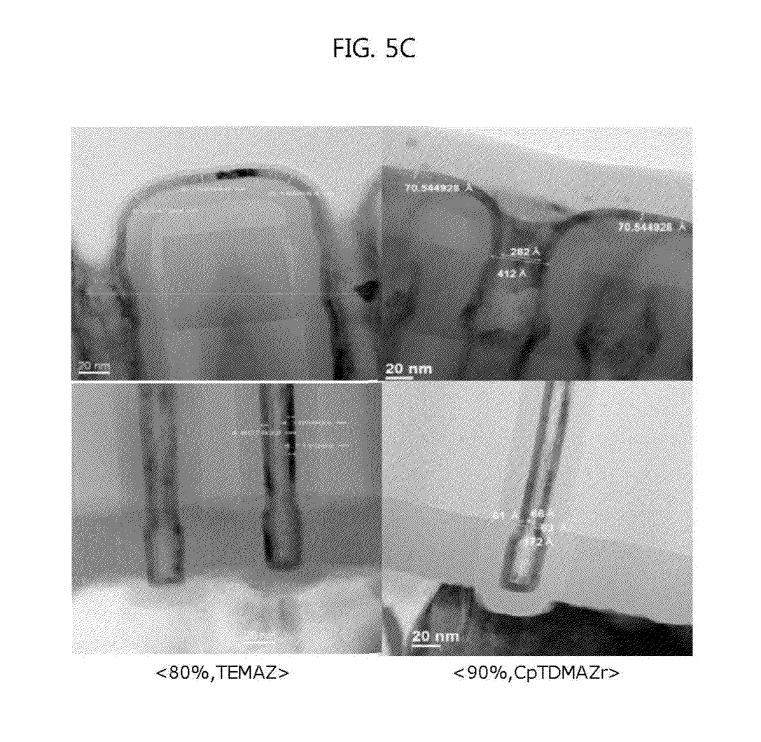

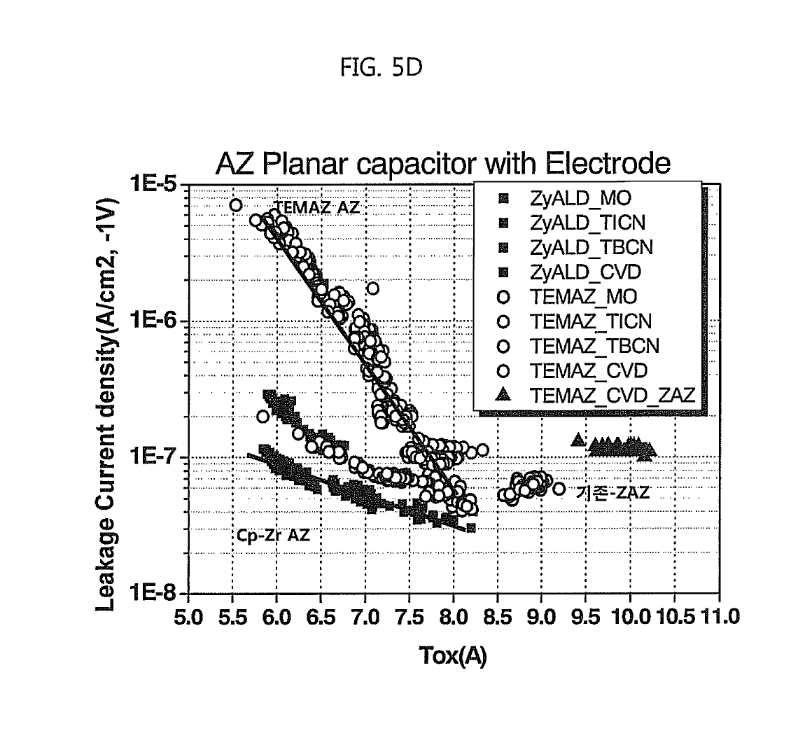

FIGS. 5A to 5D illustrate a comparison of the properties obtained by applying zirconium sources having a cyclopentadienyl ligand in accordance with an embodiment of the present invention.

Specifically, FIG. 5A illustrates a comparison of vapor pressure, FIG. 5B illustrates a comparison of deposited thickness, FIG. 5C illustrates a comparison of step coverage, and FIG. 5D illustrates a comparison of leak current characteristics.

Referring to FIG. 5A, zirconium sources having a Cp ligand have lower vapor pressure compared to TEMAZ at the same temperature. Particularly, when Cp-TDMAZr[ZrCp(NMe)₂)₃] containing a Cp ligand was used, Cp-TDMAZr[ZrCp(NMe)₂)₃] showed increased thermal stability compared to TEMAZ while Cp-TDMAZr[ZrCp(NMe)₂)₃] showed vapor pressure similar to TEMAZ. These results suggest that the atomic layer deposition (ALD) of Cp-TDMAZr[ZrCp(NMe)₂)₃] at high temperature may be performed.

Referring to FIG. 5B, the results of an actual deposition indicate that Cp-TDMAZr showed linear deposition characteristics without a rapid increase in thickness resulting from an increase in temperature. These results suggest that the ALD of Cp-TDMAZr at high temperature may be performed.

Referring to FIG. 5C, the difference in step coverage between the two sources was examined and, as a result, a 10% increase in step coverage was observed when using Cp-TDMAZr compared to TEMAZ. For example, the step coverage at an aspect ratio of 80 increases from 80% (TEMAZ) to 90% (CpTDMAZr).

Referring to FIG. 5D, the electrical properties of AZ (stack structure of Al₂O₃/ZrO₂) were examined and, as a result, when effective oxide thickness (Tax) decreased, an increase in leakage current density (LKG) was significantly lower in Cp-Zr AZ than in TEMAZ AZ. These results suggest that stable properties resulting from effective oxide thickness (Tox) scaling may be secured.

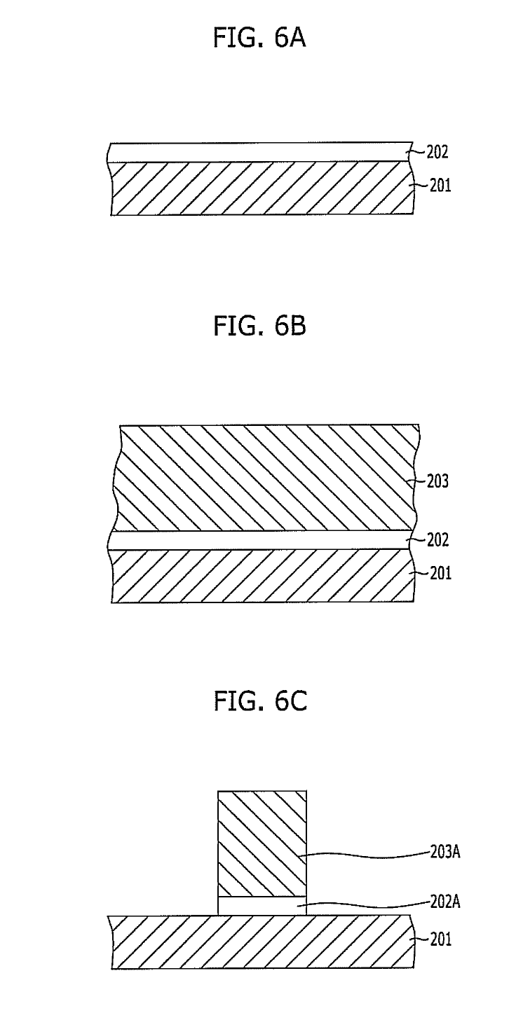

FIGS. 6A to 6C illustrate a method for fabricating a transistor comprising a multi-component dielectric layer in accordance with an embodiment of the present invention.

As shown in FIG. 6A, a gate insulating layer 202 is formed on a semiconductor substrate 201. In this embodiment, the gate insulating layer 202 may comprise a multi-component oxide in accordance with an embodiment of the present invention. For example, the gate insulating layer 202 may comprise TaZrO as shown in FIG. 2 and unit cycle 3.

As described above, the gate insulating layer 202 comprising the multi-component oxide may be formed on the semiconductor substrate 201 by the atmospheric layer deposition process using the cocktail source.

As shown in FIG. 6B, a gate conductive layer 203 is formed on the gate insulating layer 202. The gate conductive layer 203 may be a stacked layer including a polysilicon layer and a metal silicide layer such as a tungsten silicide layer. In another embodiment, a metal layer such as tungsten layer may further be formed on the metal silicide layer. Also, a gate hard mask layer may further be formed on the metal layer.

As shown in FIG. 6C, the gate conductive layer 203 is etched to form a gate electrode 203A. After the gate conductive layer 203 is etched, the gate insulating layer 202 may also be etched. The gate insulating layer that remains is indicated by reference numeral ‘202A’.

Although not shown, a source/drain region is formed on the semiconductor substrate 201 after forming the gate electrode 202A.

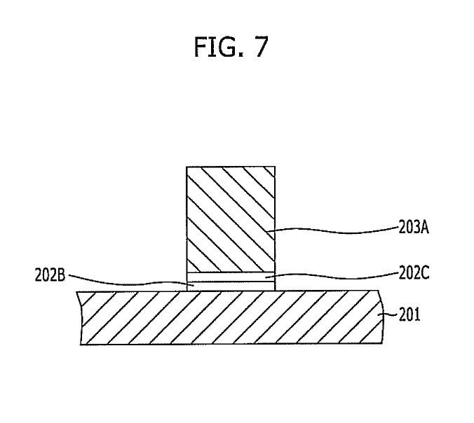

FIG. 7 illustrates a modification of a transistor comprising a multi-component dielectric layer in accordance with an embodiment of the present invention.

Referring to FIG. 7, a dielectric layer 202C for reducing leakage current may further be formed on the gate insulating layer 202B. The dielectric layer 202C may comprise the component of the gate insulating layer 202B and an oxide of at least one transition metal. In addition, the dielectric layer 202C may include a material having higher band gap energy to control leakage current characteristics. For example, the dielectric layer 202C may be formed of a material such as ZrO₂, HfO₂, Al₂O₃, Al—ZrO₂, ZrHfO₂, La₂O₃, LaHfOₓ, LaZrOₓ, ZrTaOₓ, ZrHfSiOₓ, ZrSiOₓ, HfSiOₓ or Al—HfOₓ.

The multi-component thin layer formed by the ALD process as described in the present invention may comprise an electrode material such as TiAlN, TaAlN, TiSiN or TaSiN, a multi-component oxide such as BST, STO or PZT, or a multi-component electrode material such as SRO, SZO, SIO(SrIrO₃) or TiRuO₃. Because this multi-component thin layer is deposited using a cocktail source, it may be easily deposited and may be crystallized.

The capacitor and transistor of to the present invention may be included in a memory cell and a memory cell array. The memory cell array may store or output data based on a voltage applied by a column decoder and a row decoder, which are connected with the memory cell array.

The memory cell array according to the present invention may be included in a memory device. The memory device may include a memory cell array, a row decoder, a column decoder, and a sense amplifier. The row decoder selects a word line corresponding to a memory cell, which is to perform a read operation or a write operation, from among the word lines of the memory cell array and transfers a word line selection signal to the semiconductor memory cell array. Also, the column decoder selects a bit line corresponding to a memory cell, which is to perform a read operation or a write operation, from among the bit lines of the memory cell array and transfers a bit line selection signal to the memory cell. In addition, the sense amplifiers sense data selected by the row decoder and the column decoder.

The memory device according to the present invention may be applied to DRAM (dynamic random access memory), SRAM (static random access memory), a flash memory, FeRAM (ferroelectric random access memory), MRAM (magnetic random access memory), PRAM (phase change random access memory), and the like. The previous list of memory devices is for exemplary purposes and is not intended to be limiting.

The above-described memory device may be applied mainly to desktop computers, notebook computers, and computing memories that are used in servers, as well as graphics memories of various specifications, and mobile memories. In addition, the memory device may be applied to not only portable storage media, such as memory sticks, MMCs, SDs, CFs, xD-picture cards, and USB flash devices, but also various digital applications, including MP3P, PMP, digital cameras, camcorders, and mobile phones. Also, the memory device may be applied to semiconductor device products, MCP (multi-chip package), DOC (disk-on-chip), embedded devices, and the like. Furthermore, it may also be applied to CIS (CMOS image sensor) for use in various applications, including camera phones, web cameras, and small-sized photography systems for medical use.

The memory device according to the present invention may be used in a memory module. The memory device includes a plurality of memory devices mounted on a module substrate, a command link enabling the memory devices to receive control signals (address signal, command signal, or click signal) from an external controller, and a data link that is connected with the memory devices to transmit data. For example, the command link and the data link may be formed in a manner identical or similar to those used in conventional semiconductor modules. In the memory module, 8 memory devices may be mounted on the front side of the module substrate, and the memory devices may also be mounted on the back side of the module substrate. In other words, the memory devices may be mounted on one or both sides of the module substrate, and the number of memory devices mounted is not limited. In addition, the material and structure of the module substrate are not specifically limited.

The memory module according to the present invention may be used in a memory system. The memory system includes at least one memory module having a plurality of memory devices mounted thereon, and a controller which provides a bidirectional interface between external systems to control the operation of the memory module.

The memory system according to the present invention may be used in electronic units. The electronic unit includes a memory system and a processor that is electrically connected thereto. For example, the processors include CPU (central processing unit), MPU (micro processor unit), MCU (micro controller unit), GPU (graphics processing unit), and DSP (digital signal processor). More specifically, CPU or MPU is in the form of a plurality of control units (CU), which read and analyze a command with ALU (arithmetic logic unit) to control each unit. If the processor is CPU or MPU, the electronic unit preferably comprises a computer device or a mobile device. Also, GPU is a CPU for graphic processing, which is used to calculate numbers having a decimal point and serves to draw graphics on the screen in real time. If the processor is GPU, the electronic unit preferably contains a graphic device. Also, DSP refers to a processor that converts an analog signal (e.g., sound) to a digital signal at high speed and calculates the digital signal or converts the digital signal to an analog signal again. DSP mainly calculates digital values. If the processor is DSP, the electronic unit preferably comprises sound and image devices. In addition, the processors include APU (accelerate processor unit), which is in the form of a combination of CPU and GPU and performs the role of a graphic card.

As described above, a dense dielectric layer may be formed at high temperatures according to the embodiments of the present invention. For this purpose, an improved precursor for ALD having at least one cyclopentadienyl ligand that improves the thermal stability of the precursor is used, and a mixed precursor allowing a plurality of elements to be deposited at the same time is applied. As a result, the application of the precursor to a structure may be improved, the dielectric properties of the thin layer may be improved by making the thin layer dense, the control of the layer composition may be achieved by improving the doping method, and the process may be simplified to reduce management costs and increase productivity.

In conclusion, according to the technology of the present invention, a multi-component dielectric layer and a multi-component electrode may be formed, the thickness of which may be controlled and the composition of which may be uniform. Thus, a DRAM capacitor of 30 nm scale or smaller, or a capacitor for RF devices, which requires high permittivity, may be formed.

While the present invention has been described with respect to the specific embodiments, it will be apparent to those skilled in the art that various changes and modifications may be made without departing from the spirit and scope of the invention as defined in the following claims.

What is claimed is:

1. A method of forming a multi-component layer, the method comprising:
injecting a cocktail source of a plurality of sources at least having a cyclopentadienyl ligand, wherein the cocktail source is adsorbed on a surface of a substrate by injecting the cocktail source;
performing a first purge process to remove a non-adsorbed portion of the cocktail source;
injecting a reactant to react with the adsorbed cocktail source, wherein a multi-component layer is formed by the reaction between the reactant and the absorbed cocktail source; and
performing a second purge process to remove reaction byproducts and an unreacted portion of the reactant.

2. The method of claim 1, wherein the cocktail source comprises a cocktail source of a first source comprising a first metal element (M1) and a second source comprising a second metal element (M2).

3. The method of claim 2, wherein the first source and the second source further comprise an ethyl (C₂H₅) ligand or a methyl (CH₃) ligand.

4. The method of claim 2, wherein the reactant comprises an oxygen-containing material, and the multi-component layer comprises a ‘M₁M₂O’ thin layer comprising the first metal element (M1) and the second metal element (M2).

5. The method of claim 1, wherein the multi-component layer comprises any one selected from the group consisting of TaZrO, TiAlN, TaAlN, TiSiN, TaSiN, BST, STO, PZT, SRO, SZO, SIO(SrIrO₃) and TiRuO₃.

6. A method of forming a multi-component dielectric layer, the method comprising:
injecting a cocktail source of a tantalum source having a cyclopentadienyl ligand and a zirconium source having a cyclopentadienyl ligand, wherein the cocktail source is adsorbed on a substrate by injecting the cocktail source;
performing a first purge process to remove a non-adsorbed portion of the cocktail source;
injecting an oxidant to react with the adsorbed cocktail source, wherein an oxide containing zirconium and tantalum is formed by the reaction between the oxidant and the absorbed cocktail source; and
performing a second purge process to remove reaction byproducts and an unreacted portion of the oxidant.

7. The method of claim 6, wherein the multi-component dielectric layer is formed over a surface of the substrate by atomic layer deposition method.

8. The method of claim 6, wherein the tantalum source and the zirconium source further comprise an ethyl (C₂H₅) ligand or a methyl (CH₃) ligand.

9. The method of claim 6, wherein the zirconium source comprises CpZr(N(C₂H₅)₂)₃ or CpZr(N(CH₃)₂)₃, and the tantalum source comprises CpTa(N(C₂H₅)₂)₄ or CpTa(N(CH₃)₂)₄.

10. The method of claim 6, wherein the oxidant is an oxygen-containing material.

11. A method for fabricating a capacitor, the method comprising:
forming a storage node;
reacting an oxidant with a cocktail source including a tantalum source having a cyclopentadienyl ligand and a zirconium source having a cyclopentadienyl ligand, wherein a first oxide layer containing zirconium and tantalum is formed over the storage node by the reaction between the oxidant and the cocktail source; and
forming a plate over the first oxide layer.

12. The method of claim 11, wherein, after the forming of the storage node, the method further comprises:
forming an anti-reaction layer over the surface of the storage node.

13. The method of claim 12, wherein the forming of the anti-reaction layer is performed by plasma-oxidizing the surface of the storage node.

14. The method of claim 11, wherein the forming of the first oxide layer is performed by atomic layer deposition.

15. The method of claim 11, wherein the tantalum source and the zirconium source further comprise an ethyl (C₂H₅) ligand or a methyl (CH₃) ligand.

16. The method of claim 11, wherein the zirconium source comprises CpZr(N(C₂H₅)₂)₃ or CpZr(N(CH₃)₂)₃, and the tantalum source comprises CpTa(N(C₂H₅)₂)₄ or CpTa(N(CH₃)₂)₄.

17. The method of claim 11, wherein the oxidant is an oxygen-containing material.

18. The method of claim 11, further comprising:
forming a second oxide layer over the first oxide layer before forming the plate.

19. The method of claim 18, wherein the second oxide layer is formed of a material having a band gap energy higher than that of the first oxide layer.

20. The method of claim 18, wherein the second oxide layer comprises any one selected from the group consisting of ZrO₂, HfO₂, Al₂O₃, Al—ZrO₂, ZrHfO₂, La₂O₃, LaHfOₓ, LaZrOₓ, ZrTaOₓ, ZrHfSiOₓ, ZrSiOₓ, HfSiOₓ, and Al—HfOₓ.

21. The method of claim 18, wherein the second oxide layer is formed in situ using a material having the zirconium/tantalum ratio different from that of the first oxide layer.

22. The method of claim 18, wherein the second oxide layer contains at least one metal of zirconium and tantalum.

23. A method for fabricating a transistor, the method comprising:
adsorbing a cocktail source of a tantalum source having a cyclopentadienyl ligand and a zirconium source having a cyclopentadienyl ligand on a semiconductor substrate;
reacting the cocktail source with an oxidant to form a gate insulating layer comprising an oxide layer containing zirconium and tantalum; and
forming a gate electrode over the gate insulating layer.

24. The method of claim 23, wherein, after the forming of the gate insulating layer,
forming an oxide layer over the gate insulating layer.

25. The method of claim 24, wherein the oxide layer is formed of a material having a band gap energy higher than that of the gate insulating layer.

26. The method of claim 24, wherein the oxide layer comprises any one selected from the group consisting of ZrO₂, HfO₂, Al₂O₃, Al—ZrO₂, ZrHfO₂, La₂O₃, LaHfOₓ, LaZrOₓ, ZrTaOₓ, ZrHfSiOₓ, ZrSiOₓ, HfSiOₓ, and Al—HfOₓ.

27. The method of claim 24, wherein the oxide layer is formed in situ using a material having the zirconium/tantalum ratio different from that of the gate insulating layer.

28. The method of claim 24, wherein the oxide layer contains any one metal of zirconium and tantalum.
